(19) United States
(12) Patent Application Publication
(10) Pub. No.: US 2006/0125027 A1
(43) Pub. Date: Jun. 15, 2006

(54) Nonvolatile flash memory with HfO2 nanocrystal

(75) Inventors: Chao-Hsin Chien, Taipei (TW); Ching-Tzung Lin, Taipei (TW); Yu-Hsien Lin, Taipei (TW); Chun-Yon Cheng, Taipei (TW); Tan-Fu Loi, Taipei (TW)

Correspondence Address: TROXELL LAW OFFICE PLLC;SUITE 1000, 5205 LEESBURG PIKE, FALLS CHURCH, VA, 22001, US

(73) Assignee: National Applied Research Laboratories

(21) Appl. No.: 11/008,235

(22) Filed: Dec. 10, 2004

(51) Int. Cl. H01L 29/78; H01L 21/336

(52) U.S. Cl. 257/410; 257/411

(57) ABSTRACT

In the present invention, an Hf-silicate film with small nanocrystal of high density is grown through a Rapidly Temperature Annealing (RTA) process, where its manufacturing procedure is simple and can be integrated into modern IC manufacturing procedure to be applied in related industries of memory and semiconductor, such as flash memory, nonvolatile memory, and so on, without extra equipment or process.

### FIELD OF THE INVENTION

The present invention relates to a nonvolatile flash memory; more particularly, relates to growing a hafnium silicate film having nanocrystal through a Rapidly Temperature Annealing (RTA) process, which can be applied in the industries of related memory and semiconductor, such as flash memory, nonvolatile memory, and so on.

### DESCRIPTION OF THE RELATED ARTS

Following the arrival of an epoch of high-tech, silicon (Si) has become the main material for semiconductor; and related technology of the semiconductor has influenced the public's daily life. And, following the development of the semiconductor industry, electronic products takes more regard in the material and technology of “memory”, especially those which are characterized in being light, thin, short, small and portable (for example, memories used in a mobile, a smart phone, a flash disk, a PDA (Personal Digital Assistant), and so on). Memories can be divided into categories according to whether the data stored is affected by being “powered” or not, where one category is a volatile memory and the other category is a nonvolatile one. The earliest product of a nonvolatile memory is a ROM (Read-Only-Memory), which is cheap and of high density. But, because a nonvolatile memory requires different masks for different customers, it can not be standardized for mass production and its function is considered not good enough while regarding with its cost. To solve the above problem, a memory call programmable ROM (or PROM) is provided, which requires no mask for specific user since required data is written after the memory chip is manufactured. So, it has the advantage of mass production. But, although PROM can program the ROM according to customer's requirement, its programming procedure is not simple. In response to the needs as an improvement, another kind of memory called electrically programmable ROM (or EPROM) is provided, which can be programmed by simply applying voltage after the memory chip is manufactured (as shown in FIG. 18A and FIG. 18B). Yet, because ultraviolet light (UV-light) is required for EPROM to erase data, expansive material is required on packaging.

In order to solve the above problem, a new kind of memory called electrically erasable programmable ROM (EEPROM) is proposed, which requires no UV-light except merely adding voltage to program or erase data (as sown in FIG. 19A), where a voltage is added at gate end to move electron or hole out of floating gate. For example, the FLOTOX (floating-gate tunnel-oxide) memory proposed by Intel Corp. in 1980 contains a very thin oxide layer leaning upon the drain end. The memory is not programmed by hot electron but through electron tunneling, where high voltage is added to make the electric field of the thin oxide layer become so high that Fowler-Nordheim tunneling (FN tunneling) will happen; the electron will enter into the floating gate; the drain and the source will be grounded; and so, the voltage of the gate will be added with extra +20V. On the contrary, when erasing data, the voltage at the gate end is grounded to add extra +20V to the voltage of the drain (as shown in FIG. 19B).

Because the above method needs a very thin tunnel oxide layer and the quality must be good, its manufacturing procedure becomes difficult. In addition, the working voltage it uses is too high (+20V); its layout area is too big, where each bit requires 2 cell to be stored (as shown in FIG. 20); and, the operation speed is slow (as using FN tunneling). Therefore, another kind of memory called flash memory is proposed, which is emphasized on its speed and its smaller voltage. In the other hand, its required area is smaller, where a transistor requires only one cell (1T/C) (as shown in FIG. 21). The programming of the flash memory is done by hot electron as the structure of the hot electron is obtained near the source end; yet its erasing is done by FN tunneling as a voltage is added to the gate end to move electron out of floating gate. Because it uses low voltage which adds only +5V to the drain end on programming, it is faster then, so called “Flash”, and it erases data once a sector or a block. But, it requires thin tunnel oxide, so its manufacturing procedure is still difficult.

At the same time when the mentioned FLOTOX memory is proposed, a memory structured as a Si-nitride (as shown in FIG. 22) is proposed too, called Metal Nitride-Oxide Semiconductor (MNOS), where a very thin oxide is grown on an Si wafer; a nitride is grown on the oxide then; and finally a metal is grown on top. The above method requires a very thin oxide (about tens of Å) and a nitride of good quality, which makes the manufacturing procedure difficult and so the method is not applied. Furthermore, there is an electric leakage for the MNOS at the direction from top to the gate electrode which decreases the retention time of the memory cell. So, again, another kind of flash memory with a Silicon-Oxide-Nitride-Oxide-Silicon (SONOS) structure is proposed, which adds an extra blocking oxide as comparing to the above MNOS. A charge is stored in the energy level of a Si-nitride (Si₃N₄) layer. When the charge (electron or hole) enters into the energy level of the Si-nitride layer through the tunnel oxide by incidence or jumping-out, its threshold voltage (Vt) varies as the type, the amount or the distribution of the incidence charge varies, which voltage can be distinguished as of high electric potential (for programming state) or of low electric potential (for erasing state). Hence, no interaction will happen between each two neighboring charges; local defect of the tunnel oxide will not make the whole charge be run off; and the charge stored in the energy level of the Si-nitride layer will not be run off as outside power disappears, which is also so called a nonvolatile memory. Nonetheless, it requires thin tunnel oxide and so its manufacturing procedure is still difficult.

### SUMMARY OF THE INVENTION

Therefore, the main purpose of the present invention is to provide a nonvolatile flash memory with HfO₂ nanocrystal, whose manufacturing procedure is simple and whose programming and erasing are fast.

In order to achieve the above purpose, the present invention is a nonvolatile flash Memory with HfO₂ nanocrystal, where, in an environment filled with argon and oxygen (O₂), two kinds of target materials of Si and hafnium are co-sputtered into an Hf-silicate film with a thickness of 30 Å. Then, after the materials are put into an environment of high vacuum and a O₂ is filled in and the materials are passed through RTA under 900° C. for 60 seconds, small nanocrystal of high density is obtained. Because the Hf-silicate film can trap the electric charge by using the nanocrystal, a memory with a localized storage method can be made while 2 bits can be stored in 1 cell. So, it can be applied to EEPROM, flash memory, SONOS memory, etc. in the related industries of memory and semiconductor.

### BRIEF DESCRIPTIONS OF THE DRAWINGS

The present invention will be better understood from the following detailed descriptions of the preferred embodiments according to the present invention, taken in conjunction with the accompanying drawings, in which

FIG. 1 is a view showing a manufacturing flow chart according to a first preferred embodiment of the present invention;

FIG. 2A is a view showing a cross-sectional surface of a hafnium silicate (Hf-silicate) film according to the first preferred embodiment of the present invention;

FIG. 2B is a view showing a plane surface of an Hf-silicate film according to the first preferred embodiment of the present invention;

FIG. 3A is a view showing an amorphous status of an Hf-silicate film according to the first preferred embodiment of the present invention;

FIG. 3B is a view showing a polycrystalline status of an Hf-silicate film according to the first preferred embodiment of the present invention;

FIG. 4A and FIG. 4B are views showing X-ray Photoelectron Spectrum of an Hf-silicate film according to the first preferred embodiment of the present invention;

FIG. 5 is a view showing a result of electronics measurement of an Hf-silicate film according to the first preferred embodiment of the present invention;

FIG. 6A and FIG. 6B are views showing SONOS (Silicon-Oxide-Nitride-Oxide-Silicon) structure according to a second preferred embodiment of the present invention;

FIG. 7 is a view showing a result of electronics measurement of a SONOS structure according to the second preferred embodiment of the present invention;

FIG. 8 is a view of a curving line showing a memory window of a SONOS structure according to the second preferred embodiment of the present invention;

FIG. 9A and FIG. 9B are views of curving lines showing stored charge of a SONOS structure according to the second preferred embodiment of the present invention;

FIG. 10 is a view showing working status of a SONOS structure according to the second preferred embodiment of the present invention;

FIG. 11 is a view showing curving lines of memory window of a SONOS structure according to the second preferred embodiment of the present invention;

FIG. 12A is a view showing curving lines of programming characteristic of a SONOS structure according to the second preferred embodiment of the present invention;

FIG. 12B is a view showing curving lines of erasing characteristic of a SONOS structure according to the second preferred embodiment of the present invention;

FIG. 13A through FIG. 13C are views showing curving lines of programming and erasing disturb characteristics of a SONOS structure according to the second preferred embodiment of the present invention;

FIG. 14 is a view showing curving lines of reserving characteristic of a SONOS structure according to the second preferred embodiment of the present invention;

FIG. 15 is a view showing curving lines of a durability test of a SONOS structure according to the second preferred embodiment of the present invention;

FIG. 16 is a view showing a structure of a single dot memory according to a third preferred embodiment of the present invention;

FIG. 17A is a view showing a structure of a multi-bits single dot memory before a chemical mechanical polishing (CMP) according to the third preferred embodiment of the present invention;

FIG. 17B is a view showing a structure of a multi-bits single dot memory after a CMP according to the third preferred embodiment of the present invention;

FIG. 18A and FIG. 18B are views showing an Erasable Programmable ROM (Read-Only-Memory) according to a prior art;

FIG. 19A and FIG. 19B are views showing an Electrically Erasable Programmable ROM (EEPROM) according to a prior art;

FIG. 20 is a view showing a Floating-Gate Tunnel-Oxide (FLOTOX) circuit according to a prior art;

FIG. 21 is a view showing a flash memory according to a prior art;

FIG. 22 is a view showing an MNOS (Metal Nitride-Oxide Semiconductor) memory according to a prior art;

FIG. 23 is a view showing a SONOS memory according to a prior art;

FIG. 24A is a view showing a Fowler-Nordheim tunneling (FN tunneling) band of a SONOS memory according to a prior art;

FIG. 24B is a view showing curving lines of a programming/erasing characteristic of a SONOS structure according to a prior art;

Table 1 is a table showing a result of energy dispersive spectrograph of an Hf-silicate film according to the first preferred embodiment of the present invention; and

Table 2 is a data table of a working status of a SONOS structure according to the second preferred embodiment of the present invention.

### DESCRIPTION OF THE PREFERRED EMBODIMENTS

The following descriptions of the preferred embodiments are provided to understand the features and the structures of the present invention.

The present invention provides a nonvolatile flash memory with HfO₂ nanocrystal, where, in an environment filled with argon (Ar) and oxygen (O₂), two kinds of target materials of Si and hafnium (Hf) are co-sputtered into an Hf-silicate film with a thickness of 30 Å. Then, after the materials are put into an environment of high vacuum and a O₂ is filled in and the materials are passed through Rapidly Temperature Annealing (RTA) under 900° C. for 60 seconds, nanocrystal is obtained on the Hf-silicate film, whose density lies in a range of 0.9˜1.9×10¹²cm⁻² and whose size is smaller than 10 nm (nanometer). And the nanocrystal can be used to trap the electric charge so that the storage method is made localized. Consequently, memory can be made with the above characteristics by a simple manufacturing procedure, where 2 bits can be stored in 1 cell; and can be applied to EEPROM, flash memory, SONOS memory, etc. in the related memory and semiconductor industries.

For further explanation, the present invention can be implemented into several preferred implementations as follows:

### EXAMPLE 1

### A Nonvolatile Flash Memory Prepared by Utilizing HfO₂ Nanocrystal

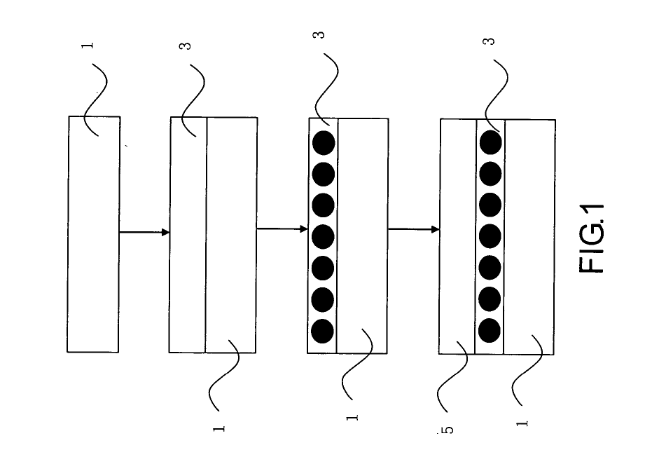

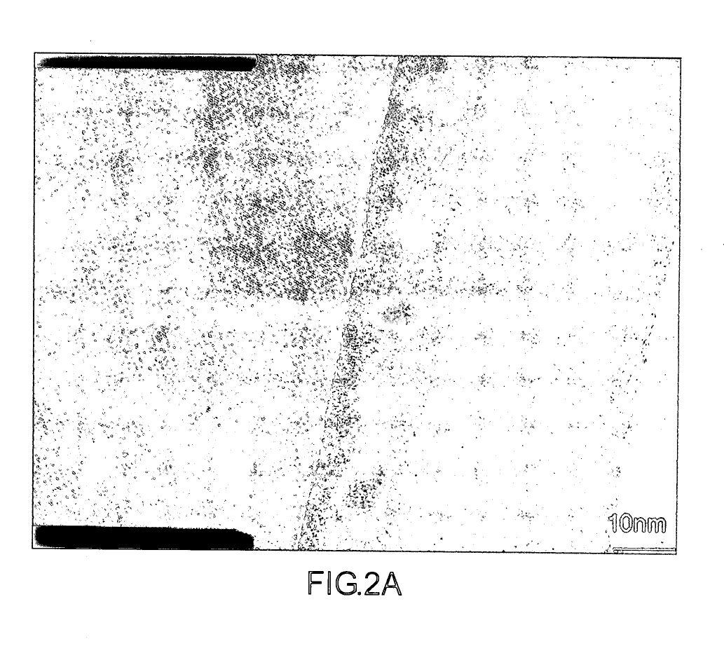

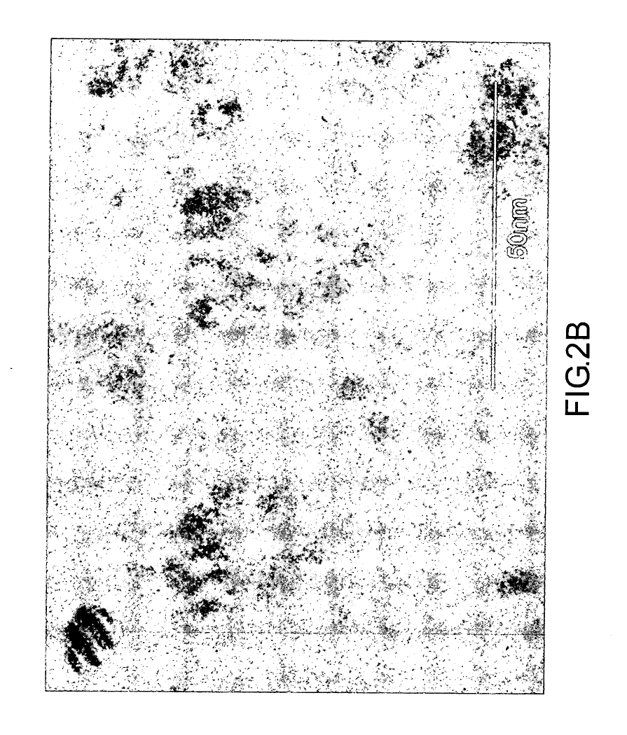

Please refer to FIG. 1 through FIG. 2B, which are views showing a manufacturing flow chart, and a cross-sectional surface and a plane surface of an Hf-silicate film, according to a first preferred embodiment of the present invention. As shown in the figures, a substrate of a p-type Si wafer is firstly put into a vacuum environment (2×10⁻⁶torr). Then, Ar and a O₂ is filled in with a current of 24 sccm/8 sccm. Two kinds of target materials of Si and Hf are then obtained to be co-sputtered into an Hf-silicate film with a thickness of 30 Å. Then, after the materials are put into an environment of high vacuum; a O₂ is filled in; and then the materials are passed through RTA under 900° C. for 60 seconds, nanocrystal is obtained on the Hf-silicate film. Its density lies in a range of 0.9˜1.9×10¹²cm⁻² and its size is smaller than 10 nm. In the end, a control gate layer 5 is obtained on the Hf-silicate film 3 by utilizing a thermal coater in forming gates, which-can be made of aluminum (Al). The above Hf-silicate film 3 may be monitored by using a Transition Electron Microscopy (TEM) to see the formation of the nanocrystal whose density lies in a range of 0.9˜1.9×10¹² cm⁻² and whose size is smaller than 10 nm.

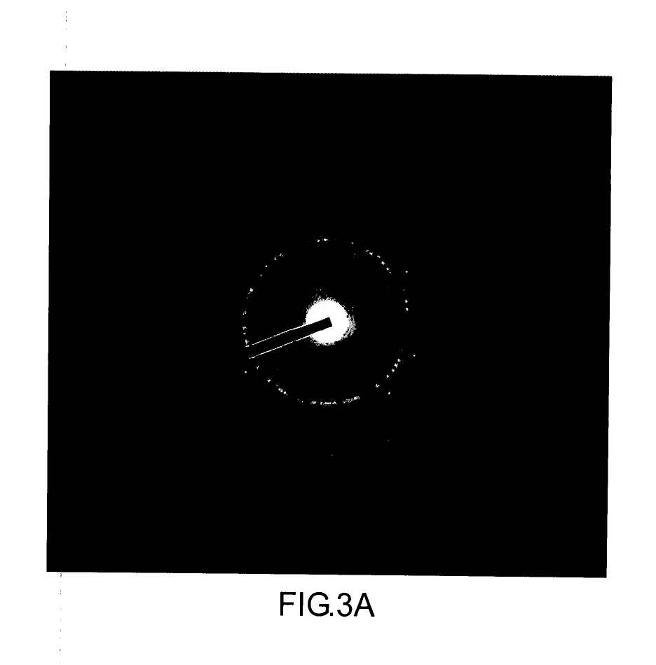

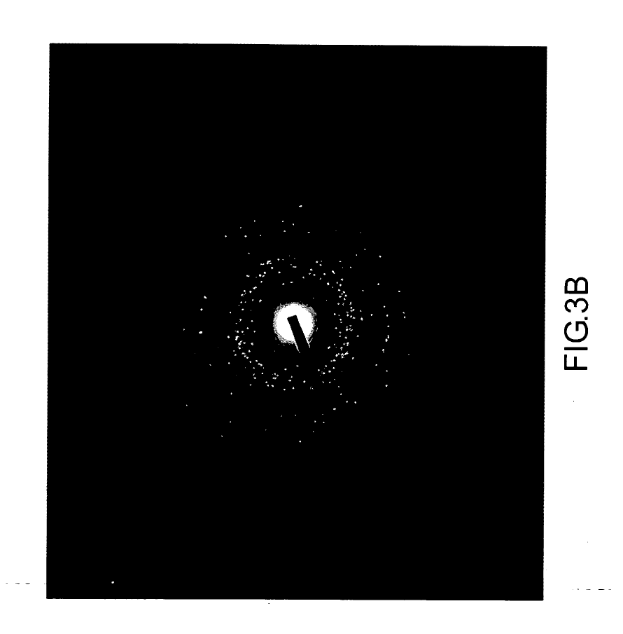

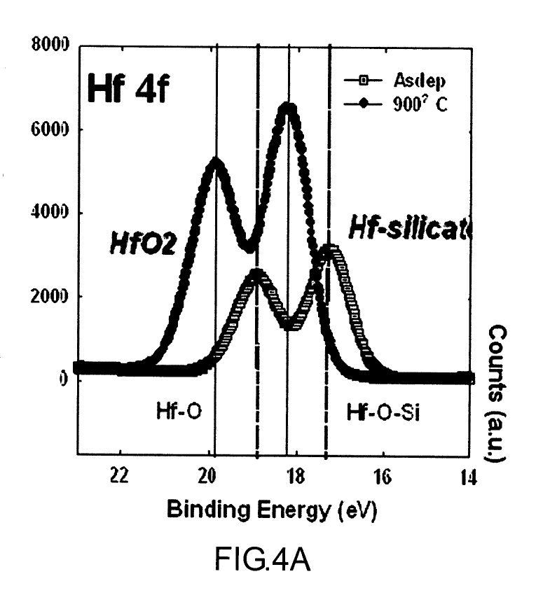

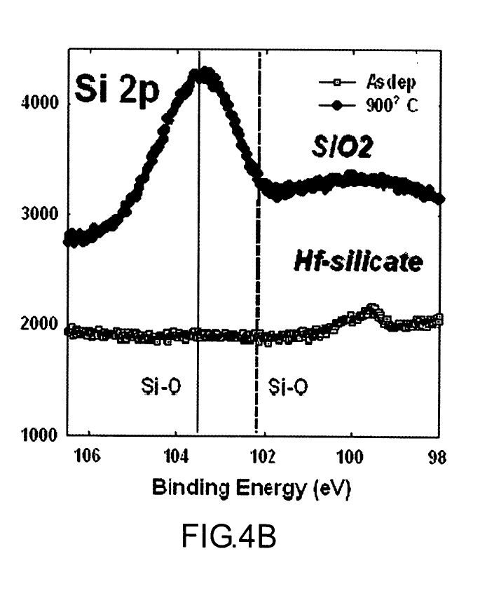

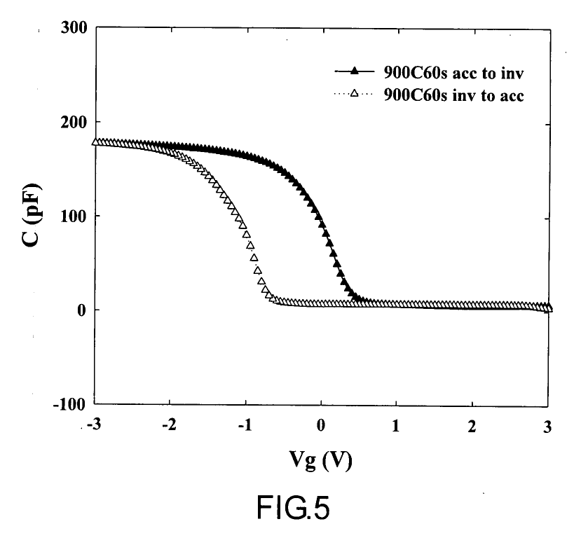

Please refer to FIG. 3A through FIG. 5 together with Table 1, which are views showing an amorphous status, a polycrystalline status, an X-ray Photoelectron Spectrum and an electronics measurement result of an Hf-silicate film, according to the first preferred embodiment of the present invention. As shown in the figures, the Hf-silicate film according to the present invention is passed through RTA under 900° C. for 60 seconds to change its elemental composition rate and its structure, where its structure is changed from an amorphous status to a polycrystalline one. And, as shown in FIG. 5, the electronics characteristics of the Charge-Voltage (C-V) for the Hf-silicate film is measured by adding 3 volt to −3 volt of voltage, where there is about 1V of memory window is opened in the C-V. In another word, the nanocrystal of the Hf-silicate film can trap the charge so that it can be applied to a memory.

### EXAMPLE 2

### A Nonvolatile Flash Memory of SONOS Prepared by Utilizing HfO₂ Nanocrystal

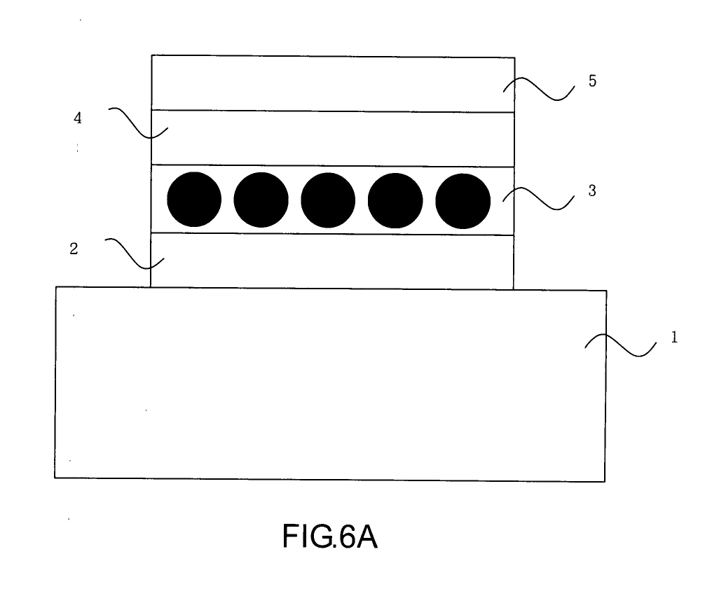

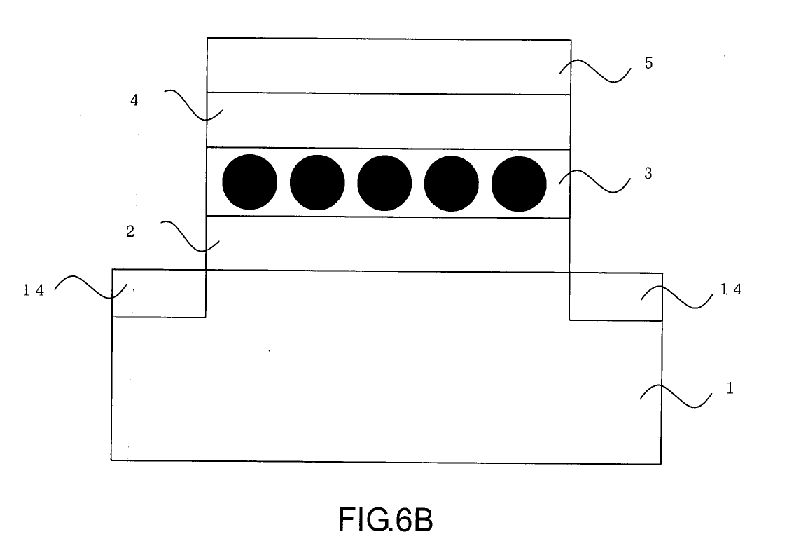

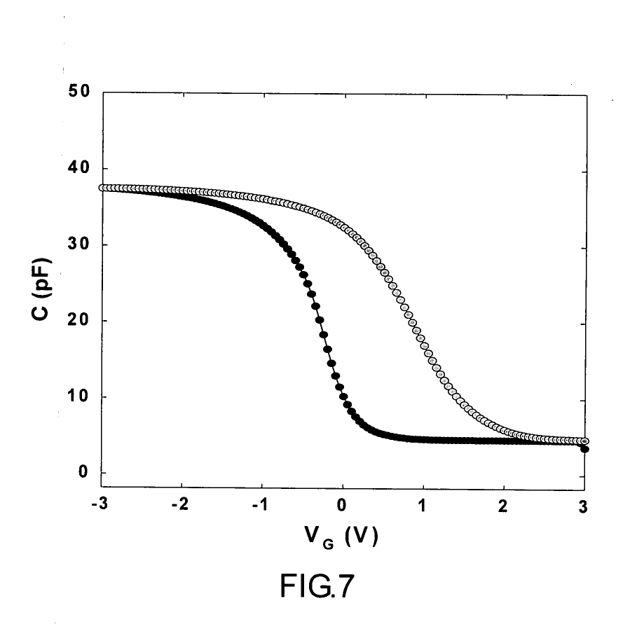

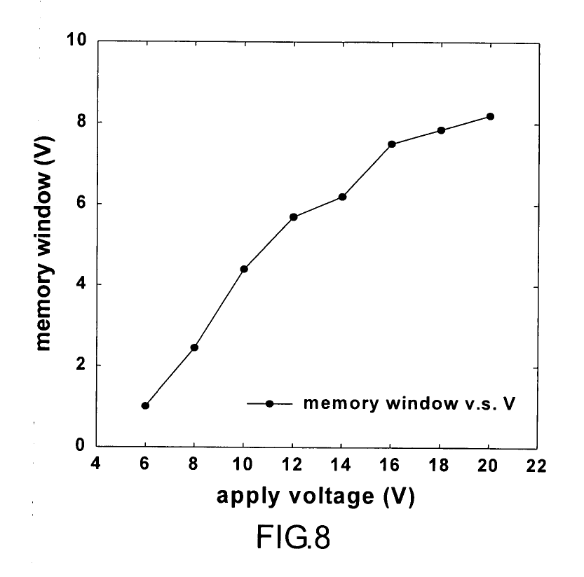

Please refer to FIG. 6A and FIG. 6B, which are views showing SONOS structure according to a second preferred embodiment of the present invention. As shown in the figures, a vertical furnace is used to grow a tunnel oxide 2 at the center on a surface of the substrate of p-type Si, where the thickness of the tunnel oxide 2 is 20 Å. The layer of the tunnel oxide 2 can be a high-k dielectric layer or a chemical vapor deposition oxide layer; and an n⁺ source or an n⁺ drain can be formed at two sides of the substrate. Then, two different target materials are used to be sputtered on the tunnel oxide 2 to form an Hf-silicate film 3 with a thickness of 30 Å by way of physical chemical synthesis (such as, atomic layer chemical vapor deposition, high-density plasma chemical vapor deposition, sputtering, or electron-gun vacuum-evaporation). The target materials can be Si and Zr (zirconium), Hf and Si, or Hf and Al, which are juxtaposed and are put into an environment of high vacuum. Then, a O₂ is filled in and they are passed through RTA under 900° C. for 60 seconds to obtain nanocrystal on the Hf-silicate film 3, where the density of the nanocrystal lies in a range of 0.9˜1.9×10¹² cm⁻² and its size is smaller than 10 nm. The Hf-silicate film can also be Zr-silicate film or Hf-aluminate film. Then, a blocking oxide 4 is grown with a thickness of 40 Å on the Hf-silicate film 3, which can be made of an oxide, a nitride, HfO₂, ZrO₂, Al₂O₃, La₂O₃. In the end, a control gate layer 5 is obtained on the blocking oxide 3 by sputtering with a material of Al, polysilicon, germanium polysilicon or a metal, through utilizing a thermal coater. Finally a SONOS-structured nonvolatile flash memory prepared by utilizing HfO₂ nanocrystal is obtained. And, as shown in FIG. 7, the electronics characteristics of C-V for the SONOS structure is measured by adding 3 volts to −3 volts of voltage, where there is about 1V of memory window is opened in the C-V. And, as shown in FIG. 8, when the voltage changes, from the smallest 6V (scanning from 3V to −3V) to the biggest 20V (scanning from 10V to −10V), the corresponding memory window formed differs.

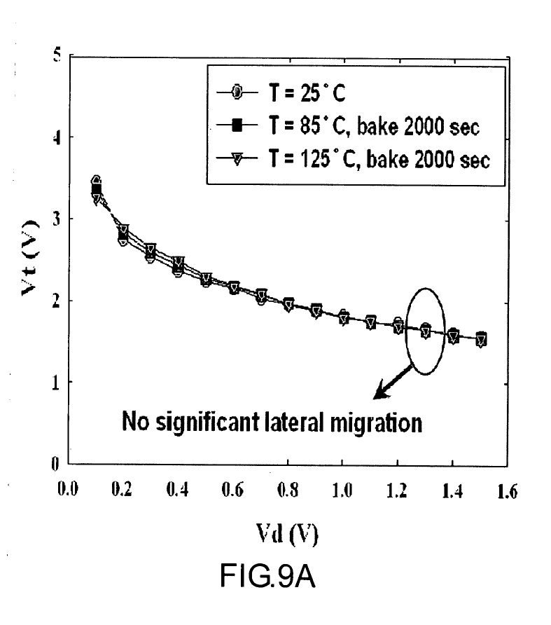

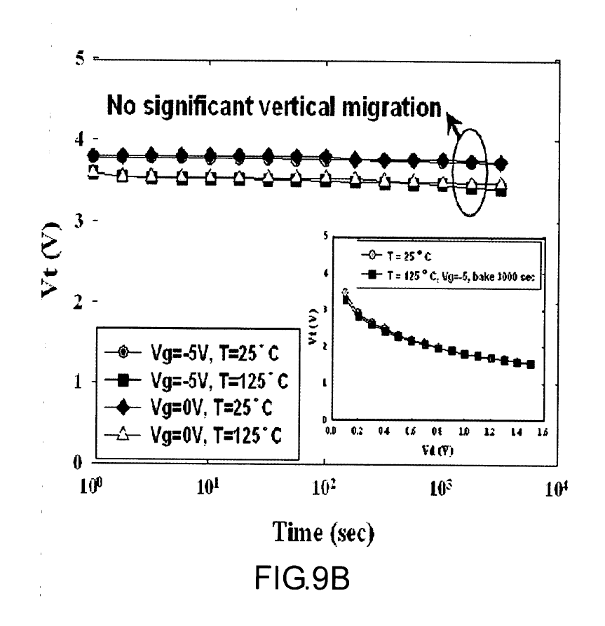

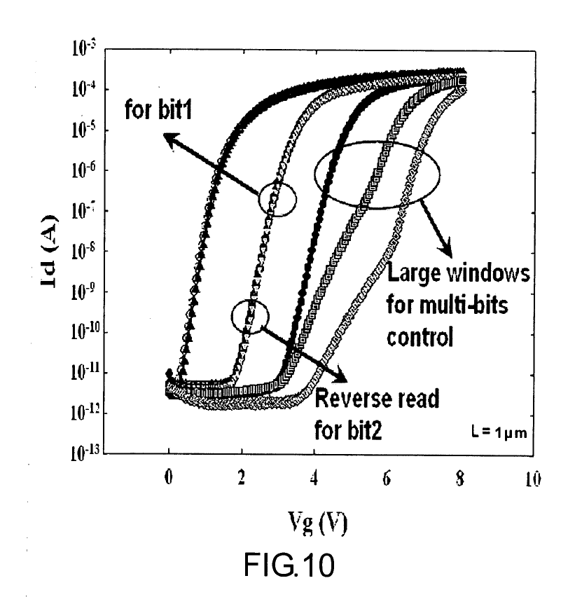

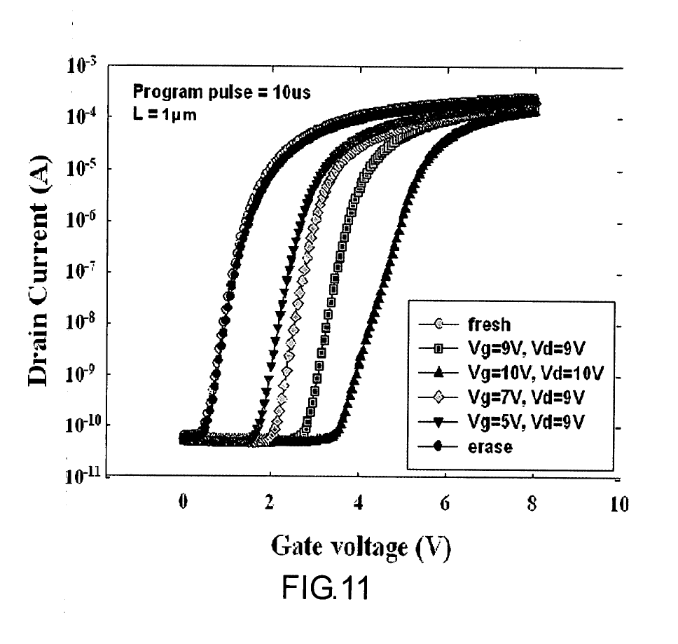

The present invention for a nonvolatile flash memory with HfO₂ nanocrystal uses physical vapor deposition to deposit an Hf-silicate film, which can be applied on any substrate. The electric charge is stored by the above Hf-silicate film in a discrete storage position so that the electric charges stored will not interact in between; and partial flaw of the tunnel oxide will not make the whole charge be drained. Because the Hf-silicate film uses every single nanocrystal to trap the electric charge, the storage method can be very localized; and so, memory can be made with this characteristic of high density to store 2 bits in 1 cell (as shown in FIG. 9A through FIG. 10 together with Table 2).

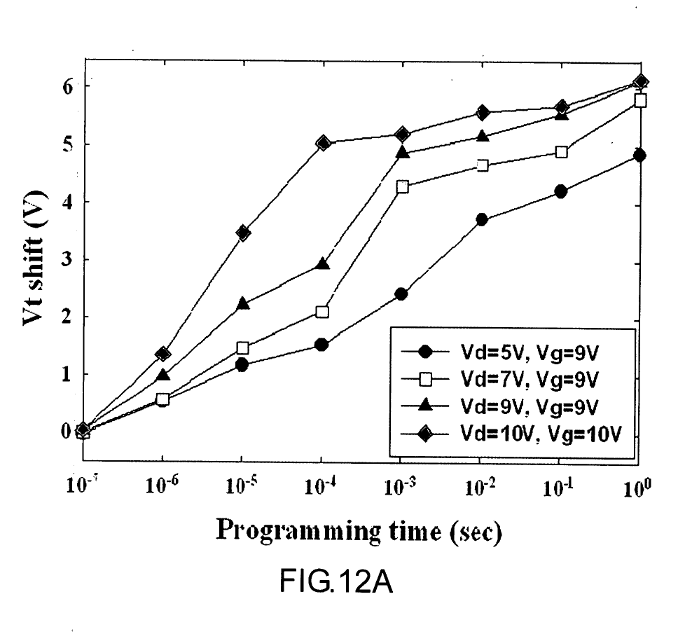

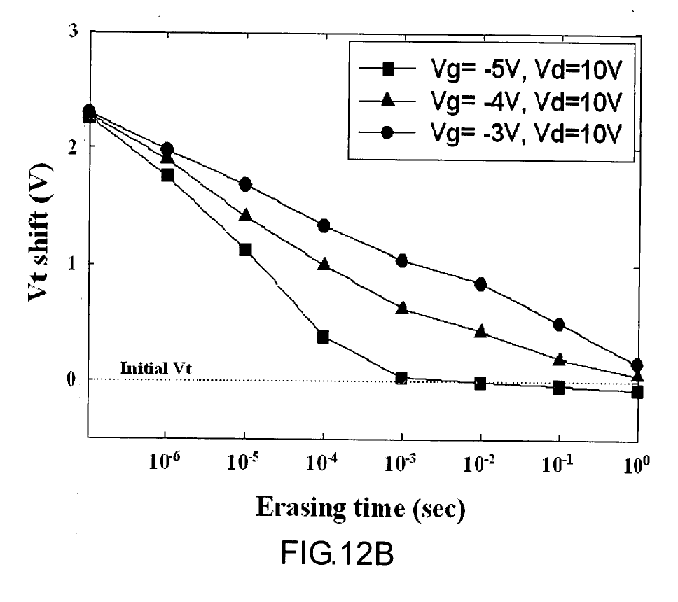

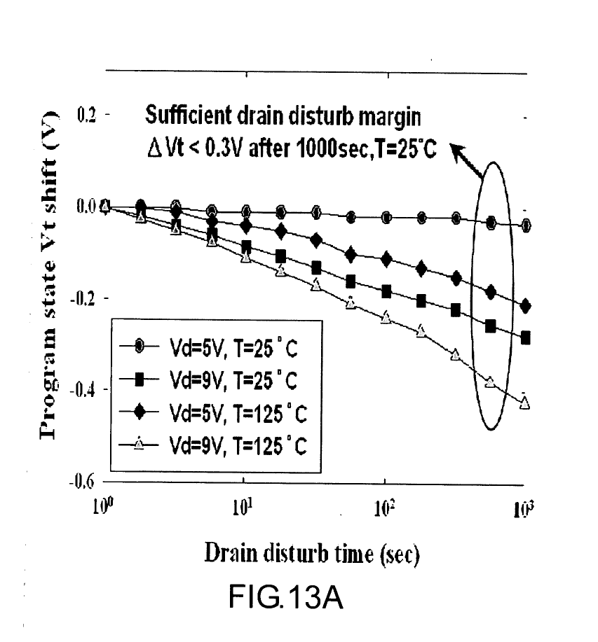

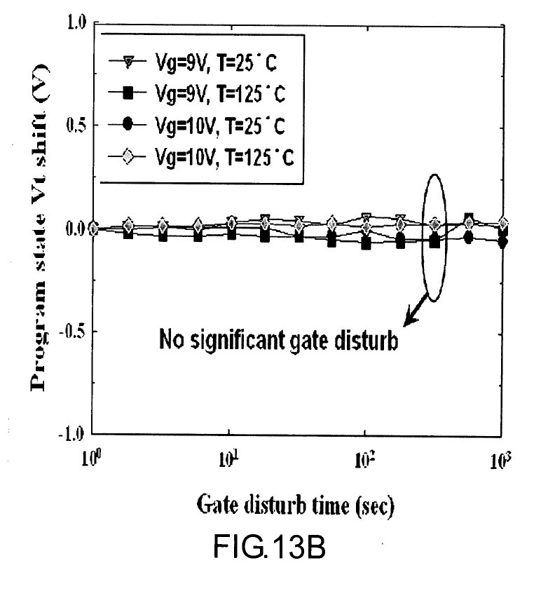

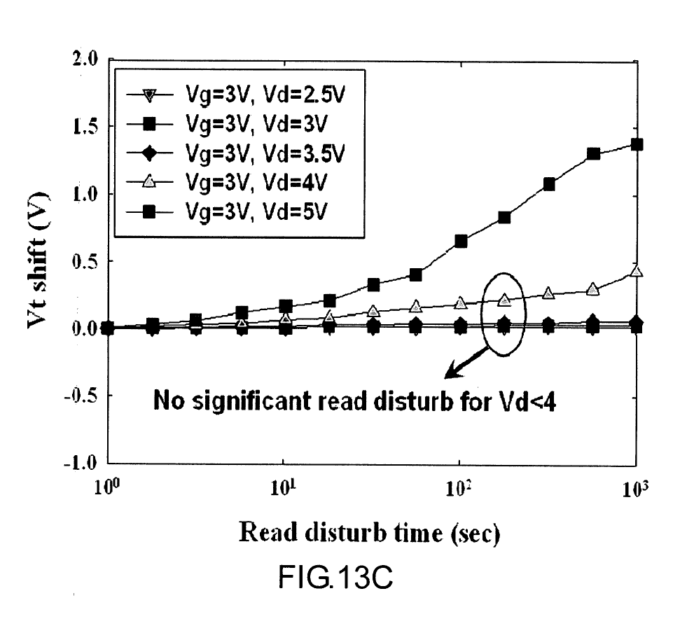

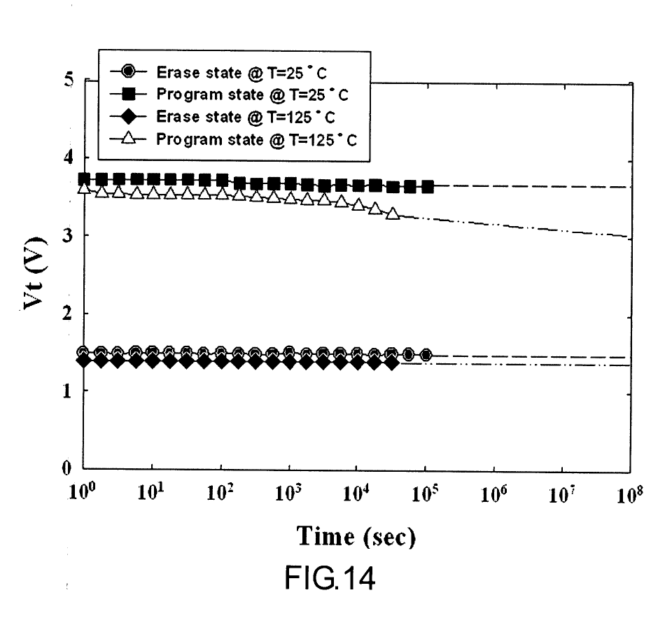

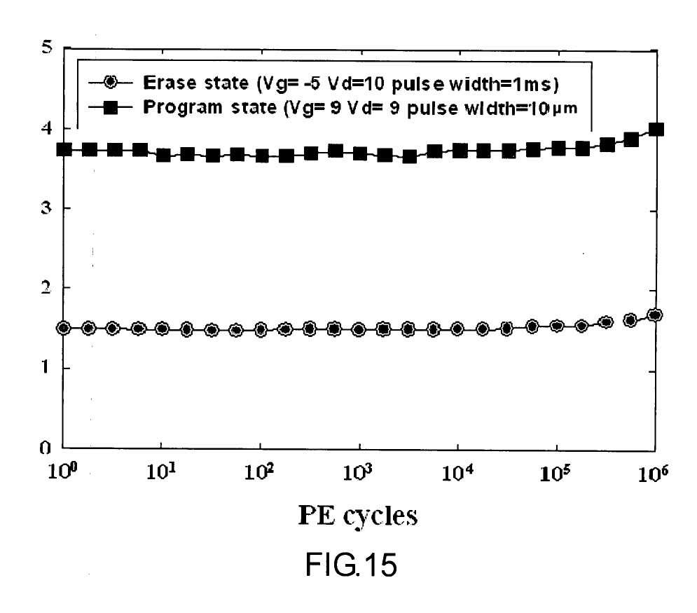

Please refer to FIG. 11 through FIG. 15, which are views showing curving lines of memory window, programming and erasing disturb characteristics, reserving characteristic, and a durability test of a SONOS structure, according to the second preferred embodiment of the present invention. As shown in the figures, the memory window of the present invention for a nonvolatile flash memory with HfO₂ nanocrystal will be increased as the Voltage (Vg) of the gate is increased so that the disturbance can be prevented on programming or erasing. Besides, no matter on programming or erasing, because the speed of incidence and that of trapping for the electric charge depend on the thickness of the tunnel oxide; and because the thickness of the tunnel oxide is 20 Å and that of the Hf-silicate film is 30 Å according to the present invention, the programming and the erasing can be fast; and a large amount of data can be kept in a long term owing to its reserving characteristic and its number of cycles being up to 10⁶.

### EXAMPLE 3

### A Nonvolatile Flash Memory of Single Dot Prepared by Utilizing HfO₂ Nanocrystal

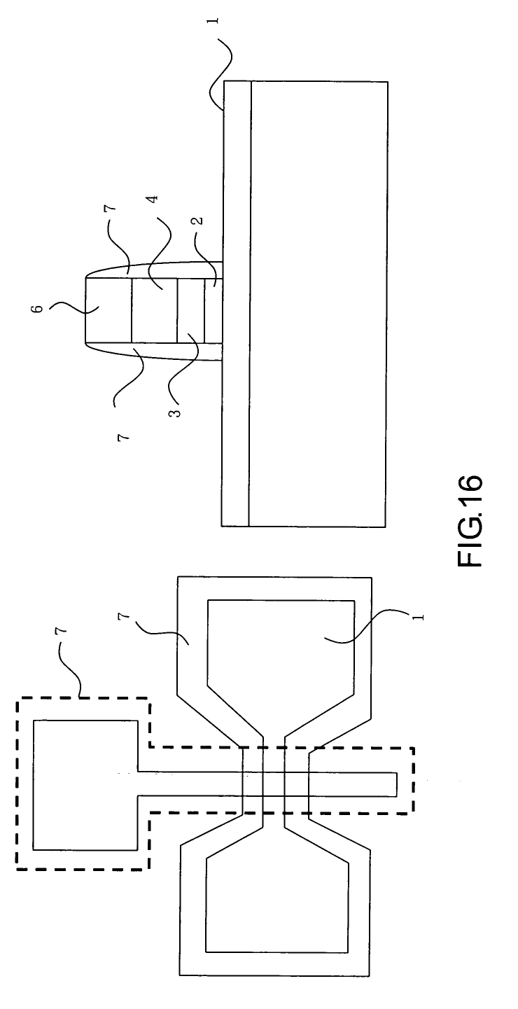

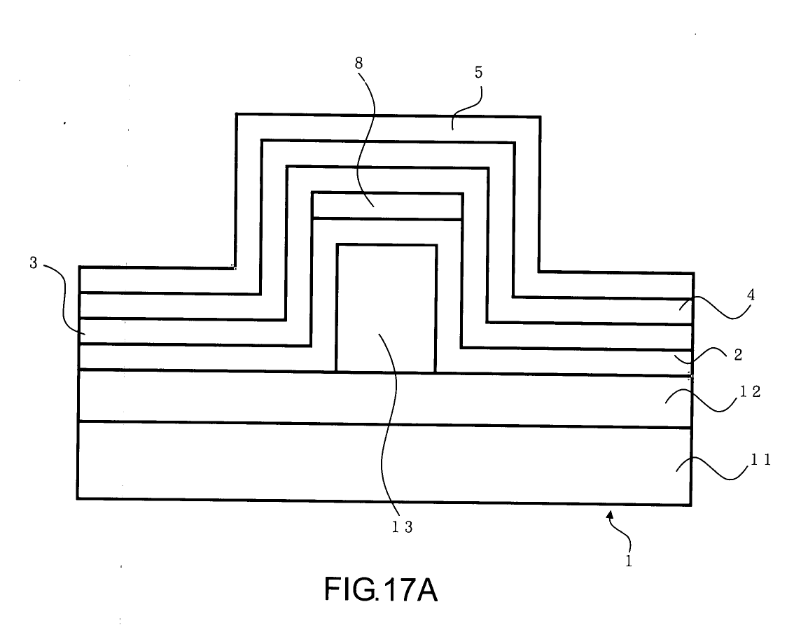

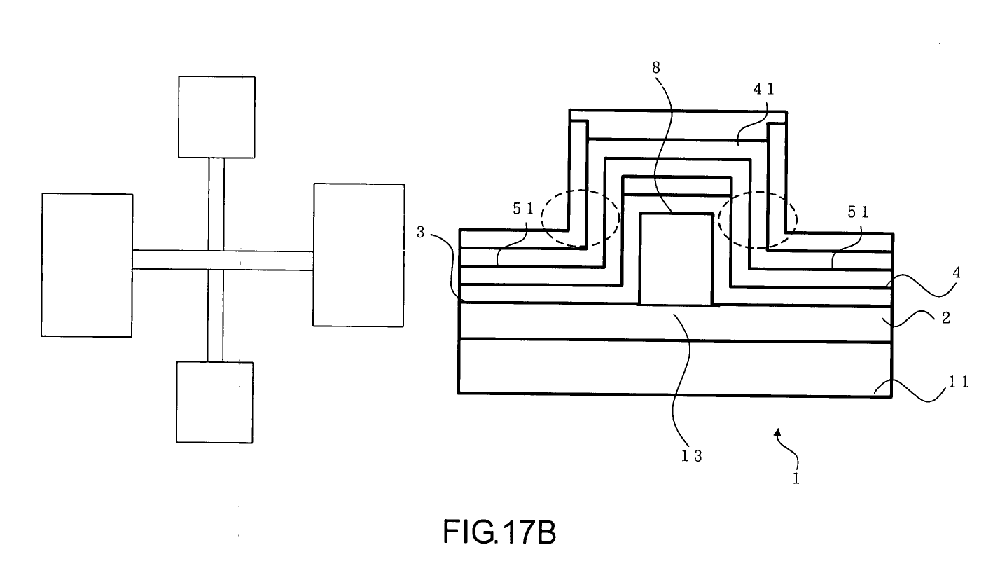

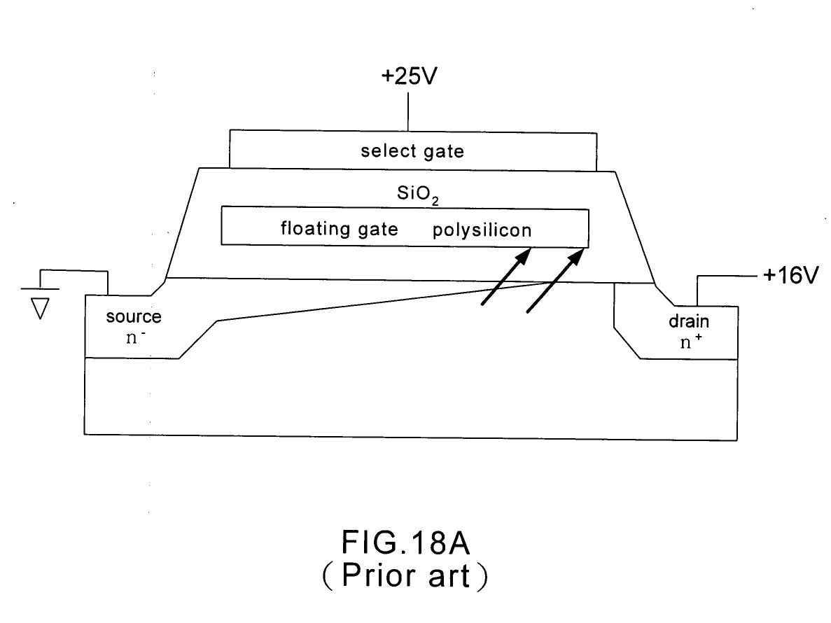

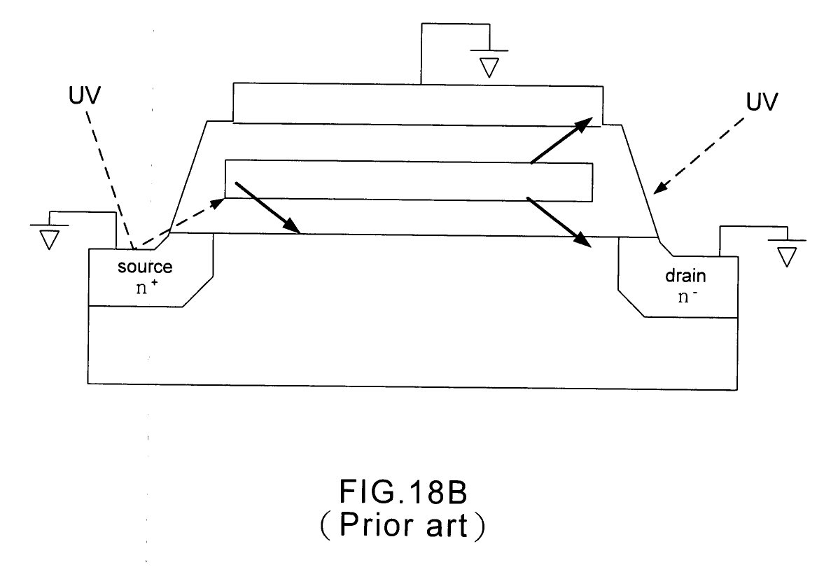

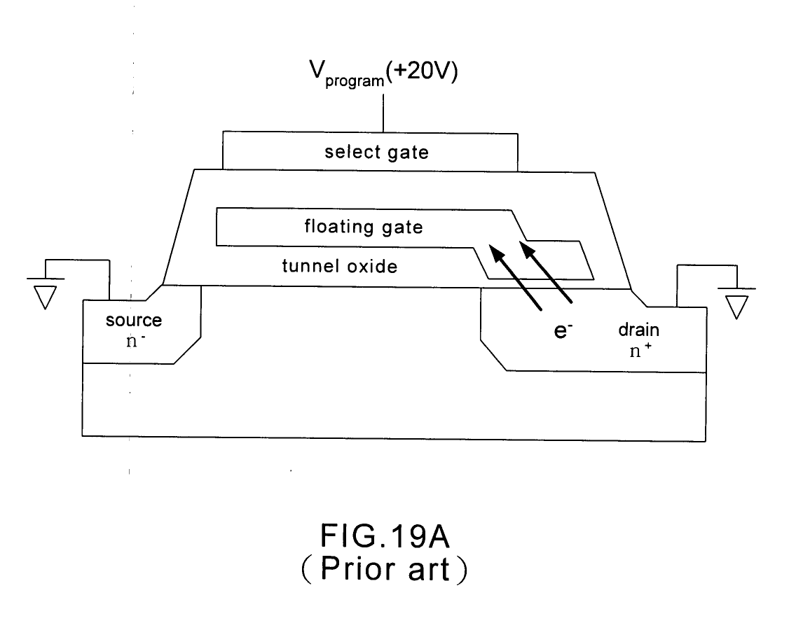

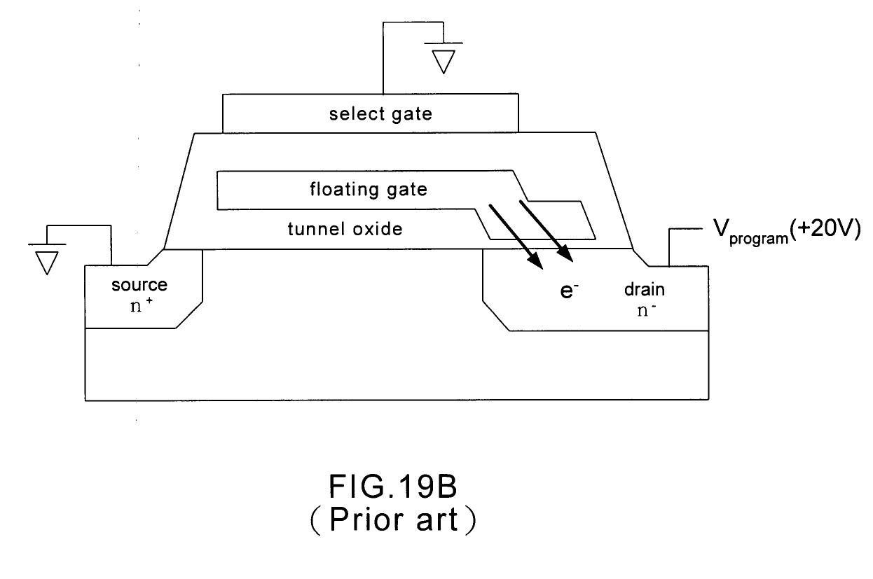

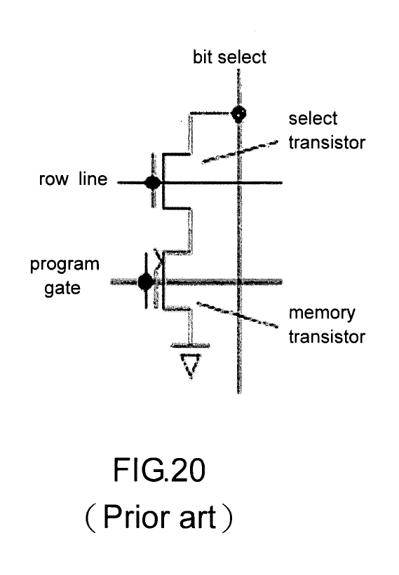

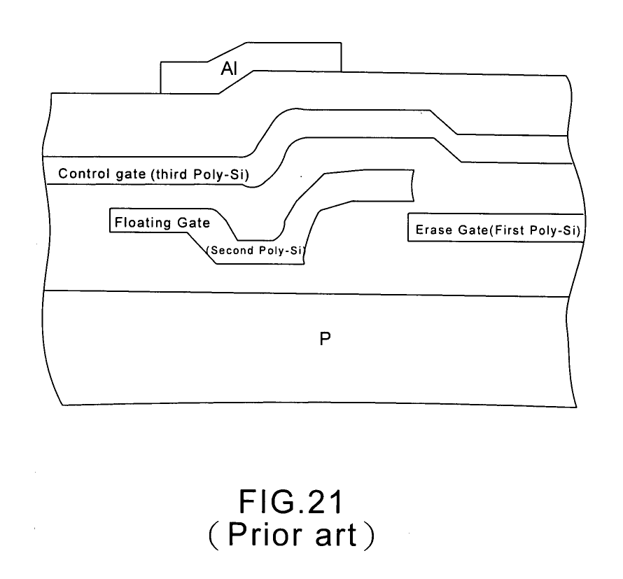

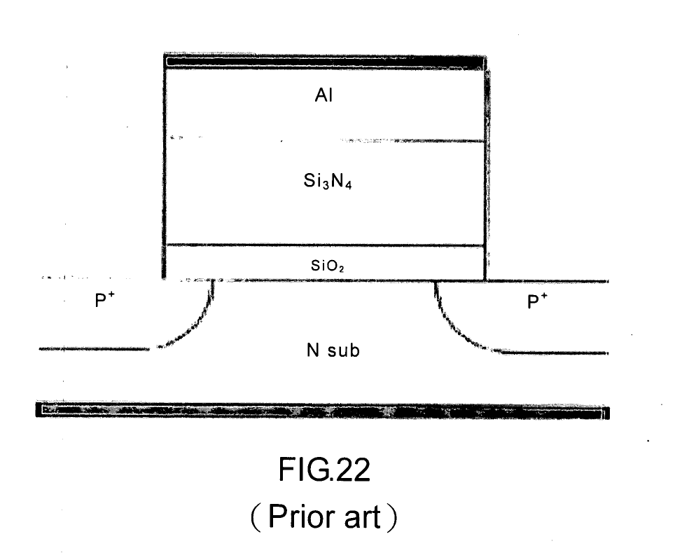

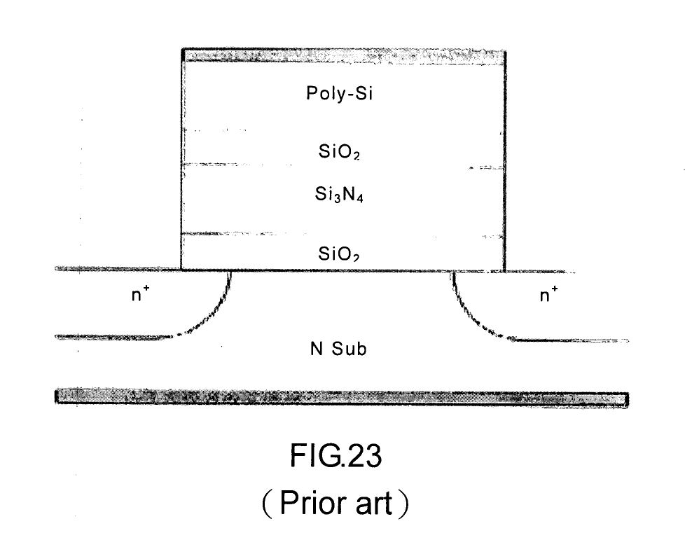

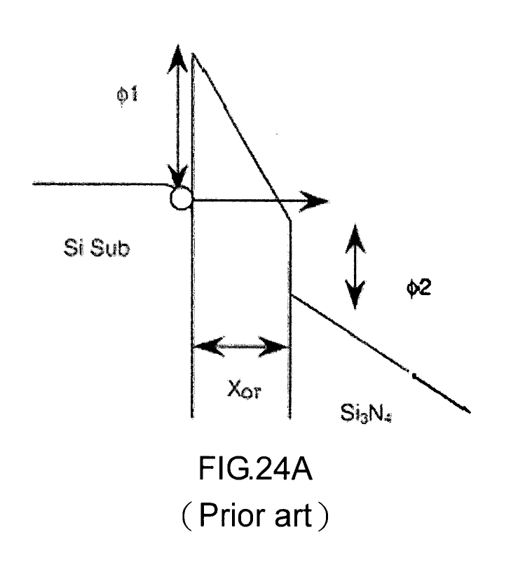

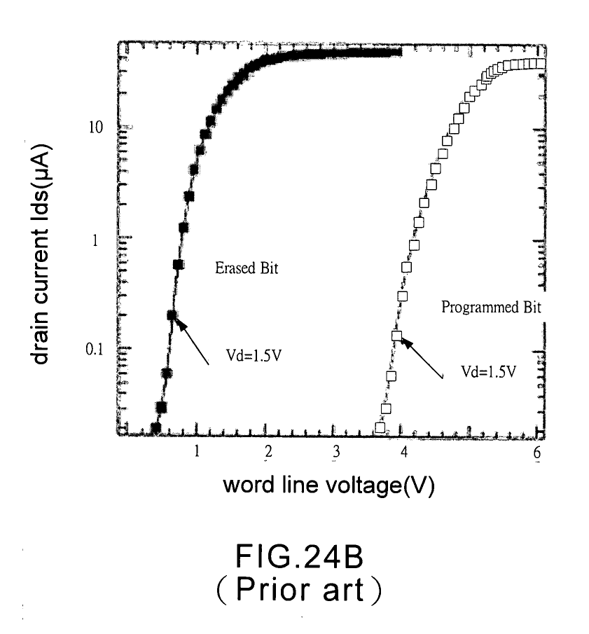

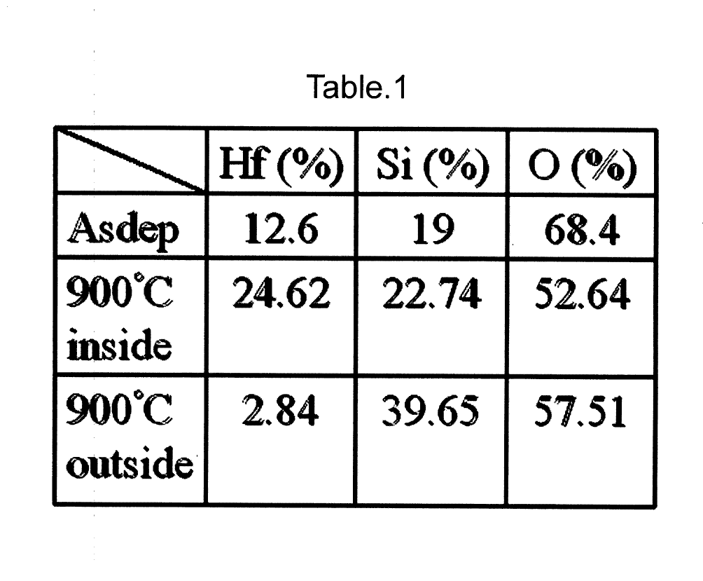

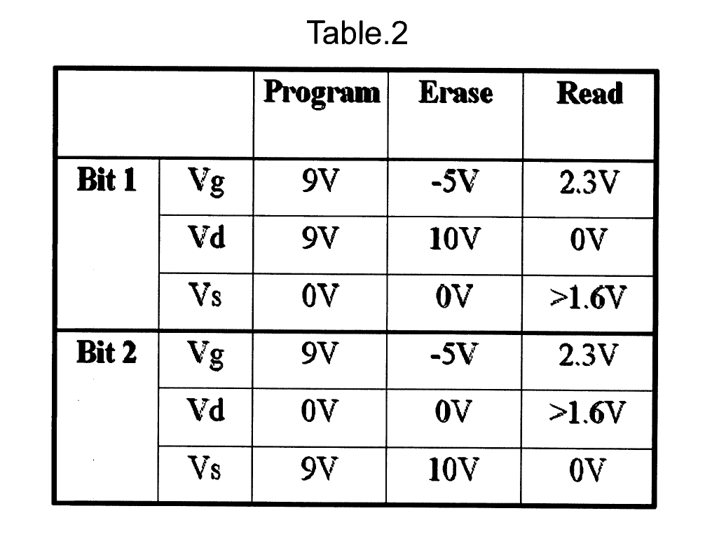

Please refer to FIG. 16 through FIG. 17B, which are views showing structures of a single dot memory, a multi-bits single dot memory before CMP and that after CMP, according to the third preferred embodiment of the present invention. As shown in the figures, a tunnel oxide 2 is grown at the center on an end surface of a substrate with a structure of SOI (Silicon-On-Insulator). Two kinds of target materials of Si and Hf are taken to be co-sputtered to form an Hf-silicate film 3 on a tunnel oxide 2 with a thickness of 30 Å. Then, after the materials are put into an environment of high vacuum and a O₂ is filled in and the materials are passed through RTA under 900° C. for 60 seconds, nanocrystal is obtained on the Hf-silicate film, whose density lies in a range of 0.9˜1.9×10¹² cm⁻² and whose size is smaller than 10 nm. Then, a blocking oxide 4 is grown on the Hf-silicate film; and a polysilicon layer 6 is grown on the blocking oxide 4, where an interval layer 7 is grown on the two sides of the tunnel oxide 2, the Hf-silicate film 3, the blocking oxide 4, and the polysilicon layer so that a nonvolatile flash memory of single dot is formed by utilizing HfO₂ nanocrystal.

### EXAMPLE 4

### A Nonvolatile Flash Memory of Muti-Bits Single-Dot Prepared by Utilizing HfO₂ Nanocrystal

Please refer to FIG. 17A and FIG. 17B, which are views showing structures of a multi-bits single dot memory before a CMP and that after the polishing according to the third preferred embodiment of the present invention. As shown in the figures, the present invention comprises a substrate structured as SOI, where a SiO₂ layer 12 is formed on a first Si layer 11; and a second Si layer 13 is formed at the center on an end surface of the SiO₂ layer. Then, a tunnel oxide is formed on two sides of the end surface of the tunnel oxide and upon the second Si layer 13; and an Hf-silicate film is formed again on the tunnel oxide 2. The Hf-silicate film 3 is formed on the tunnel oxide 2 by co-sputtering the two target materials of Hf and Si, whose thickness is 30 Å. Then, it is put into an environment of high vacuum. After a O₂ is filled in and the materials are passed through RTA under 900° C. for 60 seconds, nanocrystal is obtained on the Hf-silicate film 3, whose density lies in a range of 0.9˜1.9×10¹² cm⁻² and whose size is smaller than 10 nm. Then, a hard mask made of Si₃N₄ is formed on an end surface between the tunnel oxide 2 and the Hf-silicate film 3; a blocking oxide 4 is formed on the Hf-silicate film 3; and a control gate layer 5 is formed on the blocking oxide 4 (as shown in FIG. 17A). In the end, part of the control gate layer 5 upon an end surface of the blocking oxide 4 is removed by way of CMP to get control gates so that a nonvolatile flash memory of muti-bits single-dot prepared by utilizing HfO₂ nanocrystal is obtained.

To sum up, by using an Hf-silicate film as the main tactic, the present invention can overcome the defects of the prior arts and obtain advantages of easy manufacturing, fast programming or erasing the memory, high density, reserving characteristic, better resistance, and so on.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A nonvolatile flash memory with HfO₂ nanocrystal, at least comprising:
a substrate;
a hafnium-silicate (Hf-silicate) film deposed on said
substrate; and
a control gate layer formed on said Hf-silicate film.

2. The nonvolatile flash memory according to claim 1, wherein said substrate is a p-type silicon wafer.

3. The nonvolatile flash memory according to claim 1, wherein said substrate is put into a vacuum environment.

4. The nonvolatile flash memory according to claim 3, wherein said vacuum environment is filled with argon (Ar) and oxygen (O₂).

5. The nonvolatile flash memory according to claim 1, wherein a method for preparing said Hf-silicate film at least comprises steps of:
(a) obtaining an Hf and an Si as target materials to be co-sputtered to obtain said Hf-silicate film; and
(b) in an environment of high vacuum with O₂, passing said Hf-silicate film through a Rapidly Temperature Annealing (RTA) under 900 for 60 seconds to obtain nanocrystal on said Hf-silicate film.

6. The nonvolatile flash memory according to claim 5, wherein the density of said nanocrystal is a value between 0.9×10¹² cm⁻² and 1.9×10¹² cm⁻².

7. The nonvolatile flash memory according to claim 5, wherein the size of said nanocrystal is smaller than 10 nm (nanometer).

8. The nonvolatile flash memory according to claim 1, wherein the thickness of said Hf-silicate film is thinner than 30?.

9. The nonvolatile flash memory according to claim 1, wherein said control gate layer is formed on said Hf-silicate film by using a thermal coater.

10. The nonvolatile flash memory according to claim 1, wherein said control gate layer is made of aluminum (Al).

11. A nonvolatile flash memory with HfO₂ nanocrystal, at least comprising:
a substrate;
a tunnel oxide grown at the center on an end surface of said substrate by using a vertical furnace;
an Hf-silicate film formed on said tunnel oxide;
a blocking oxide deposited on said Hf-silicate film by way of Plasma Enhance Chemical Vapor Deposition; and
a control gate layer formed on said blocking oxide.

12. The nonvolatile flash memory according to claim 11, wherein said substrate is a p-type Si wafer.

13. The nonvolatile flash memory according to claim 11, wherein formed at two sides of said substrate is selected from a group consisting of an n⁺ source and an n⁺ drain.

14. The nonvolatile flash memory according to claim 11, wherein a method for preparing said Hf-silicate film at least comprises steps of:
(a) obtaining an Hf and an Si as target materials to obtain said Hf-silicate film through physical chemical synthesis; and
(b) in an environment of high vacuum with O₂, passing said Hf-silicate film through an RTA under 900 for 60 seconds to obtain nanocrystal on said Hf-silicate film.

15. The nonvolatile flash memory according to claim 14, wherein said physical chemical synthesis is a method of selected from a group consisting of Atomic Layer Chemical Vapor Deposition, High-Density Plasma Chemical Vapor Deposition, sputtering and Electron-Gun Vacuum-Evaporation.

16. The nonvolatile flash memory according to claim 14, wherein said Hf-silicate film is further selected from a zirconium silicate (Zr-silicate) film and an Hf-aluminate film.

17. The nonvolatile flash memory according to claim 14, wherein the density of said nanocrystal is a value between 0.9×10¹² cm⁻² and 1.9×10¹² cm⁻².

18. The nonvolatile flash memory according to claim 14, wherein the size of said nanocrystal is smaller than 10 nm.

19. The nonvolatile flash memory according to claim 11, wherein the thickness of said Hf-silicate film is thinner than 30?.

20. The nonvolatile flash memory according to claim 11, wherein the thickness of said tunnel oxide is 20?.

21. The nonvolatile flash memory according to claim 11, wherein said tunnel oxide is a chemical vapor deposition oxide.

22. The nonvolatile flash memory according to claim 11, wherein said tunnel oxide is a high-k dielectric.

23. The nonvolatile flash memory according to claim 11, wherein the thickness of said blocking oxide is 40?.

24. The nonvolatile flash memory according to claim 11, wherein said blocking oxide is made of a material selected from a group consisting of an oxide, a nitride, HfO₂, ZrO₂, Al₂O₃ and La₂O₃.

25. The nonvolatile flash memory according to claim 11, wherein said control gate layer is formed on said Hf-silicate film by using a thermal coater.

26. The nonvolatile flash memory according to claim 11, wherein said control gate layer is made of a material selected from a group consisting of Al, polysilicon, germanium polysilicon and a metal.

27. The nonvolatile flash memory according to claim 11, wherein the structure of said nonvolatile flash memory is a SONOS (Silicon-Oxide-Nitride-Oxide-Silicon) structure.

28. A nonvolatile flash memory with HfO₂ nanocrystal, at least comprising:
a substrate;
a tunnel oxide grown at the center on an end surface of said substrate;
an Hf-silicate film formed on said tunnel oxide;
a blocking oxide formed on said Hf-silicate film;
a polysilicon formed on said blocking oxide; and
an interval layer formed at two sides of said tunnel oxide, said Hf-silicate film, said blocking oxide, and said polysilicon.

29. The nonvolatile flash memory according to claim 28, wherein said nonvolatile flash memory is a single dot memory.

30. The nonvolatile flash memory according to claim 28, wherein the structure of said substrate is a SOI (Silicon-On-Insulator) structure.

31. The nonvolatile flash memory according to claim 28, wherein a method for preparing said Hf-silicate film at least comprises steps of:
(a) obtaining an Hf and an Si as target materials to be co-sputtered to obtain said Hf-silicate film; and
(b) in an environment of high vacuum with O₂ passing said Hf-silicate film through an RTA under 900 for 60 seconds to obtain nanocrystal on said Hf-silicate film.

32. The nonvolatile flash memory according to claim 31, wherein the density of said nanocrystal is a value between 0.9×10¹² cm⁻² and 1.9×10¹² cm⁻².

33. The nonvolatile flash memory according to claim 31, wherein the size of said nanocrystal is smaller than 10 nm.

34. The nonvolatile flash memory according to claim 28, wherein the thickness of said Hf-silicate film is thinner than 30?.

35. A nonvolatile flash memory with HfO₂ nanocrystal, at least comprising:
a substrate including a first Si layer on a SiO₂ layer and a second Si layer grown at the center on an end surface of said SiO₂ layer;
a tunnel oxide formed at two sides on an end surface of said SiO₂ layer and upon said second Si layer;
an Hf-silicate film formed on said tunnel oxide;
a hard mask formed on an end surface between said tunnel oxide and said Hf-silicate film;
a blocking oxide formed on said Hf-silicate film; and
a control gate layer formed on said blocking oxide,
wherein a plurality of control gates is formed in a way of chemical mechanical polishing (CMP) on said control gate layer by removing the part of said control gate layer which is right upon an end surface of said blocking oxide.

36. The nonvolatile flash memory according to claim 35, wherein said nonvolatile flash memory is a multi-bits single-dot memory.

37. The nonvolatile flash memory according to claim 35, wherein the structure of said substrate is a SOI structure.

38. The nonvolatile flash memory according to claim 35, wherein a method for preparing said Hf-silicate film at least comprises steps of:
(a) obtaining an Hf and an Si as target materials to be co-sputtered to obtain said Hf-silicate film; and
(b) in an environment of high vacuum with 02, passing said Hf-silicate film through an RTA under 900 for 60 seconds to obtain nanocrystal on said Hf-silicate film.

39. The nonvolatile flash memory according to claim 38, wherein the density of said nanocrystal is a value between 0.9×10¹² cm⁻² and 1.9×10¹² cm².

40. The nonvolatile flash memory according to claim 38, wherein the size of said nanocrystal is smaller than 10 nm.

41. The nonvolatile flash memory according to claim 35, wherein the thickness of said Hf-silicate film is thinner than 30?.

42. The nonvolatile flash memory according to claim 35, wherein said hard mask is made of Si₃N₄.
